(19) United States
(12) Patent Application Publication
(10) Pub. No.: US 2024/0266243 A1
(43) Pub. Date: Aug. 8, 2024

(54) SYSTEM IN A PACKAGE (SIP) THERMAL MANAGEMENT

(71) Applicant: OCTAVO SYSTEMS LLC, Sugar Land, TX (US)

(72) Inventors: Eshtaartha BASU, Sugar Land, TX (US); Erik James WELSH, Bellaire, TX (US); Masood MURTUZA, Sugar Land, TX (US)

(73) Assignee: OCTAVO SYSTEMS LLC, Sugar Land, TX (US)

(21) Appl. No.: 18/565,785

(22) PCT Filed: May 31, 2022
(86) PCT No.: PCT/US2022/031613

§ 371 Date: Nov. 30, 2023

Related U.S. Application Data
(60) Provisional application No. 63/195,480, filed on Jun. 1, 2021.

(51) Int. Cl. H01L 23/367; H01L 23/31; H01L 23/498; H01L 25/16

(52) U.S. Cl. CPC H01L 23/367; H01L 23/3128; H01L 23/49811; H01L 25/16

(57) ABSTRACT

A unified design process for a System in a Package (SiP) device that includes optimizing desired thermal performance, including methods and structures for optimizing the thermal management of the SiP. A plurality of active components are separated by one or more thermal barriers. The proper thermal testing location may be indicated on a surface of the SiP packaging.

### TECHNICAL FIELD

This disclosure relates to thermal considerations and management techniques for the design and fabrication of a System in a Package (SiP) device, and in particular, with specified, deterministic, managed, and/or improved thermal and operational behaviors.

### BACKGROUND

System-on-a-Chip (“SoC”) refers to a device currently used in the semiconductor industry that incorporates different functional circuit blocks on a single monolithic block of silicon to form one system circuit. Systems in a Package (“SiP”) devices are currently used in the semiconductor industry to assemble multiple integrated circuits (packaged or unpackaged), other devices, and passive components in one semiconductor package.

SiPs enable integration of devices with diverse fabrication technologies, such as digital, analog, optical, and memory devices along with other devices and components such as discrete circuits, various non-silicon devices, sensors, and power management, as well as other SiPs. Therefore, SiPs can provide heterogeneous integrations of systems that are otherwise impossible or impractical to integrate, for instance, in a single silicon circuit such as an ASIC or SoC. These other discrete circuits may include, but are not limited to, non-silicon-based circuits, such as organic, germanium, Gallium Nitride (GaN), or organic based components. SiPs are also attractive because they can allow miniaturization of microelectronic systems from a printed circuit board (which may be tens of square cm in size) to often a single package of a square cm or less. Another benefit of a SiP is that it can allow for building prototypes to test a system prior to further integration of some of the components into a single monolithic silicon circuit, where it is possible to later employ SoC technology to produce a SoC.

There remains a need for improved thermal design and management of packaged devices, including for SiP devices.

### SUMMARY

According to embodiments, a System in a Package (SiP) apparatus is provided that comprises: a substrate; a first active device mounted on the substrate; a second active device mounted on the substrate; and a thermal barrier that thermally isolates the first device from the second device. In certain aspects, the thermal barrier may be comprised of a plurality of discrete passive components in an array configuration, such as a plurality of surface-mount resistors. In some embodiments, the thermal barrier may comprise one or more vias that extend from the top surface of the substrate to the bottom surface of the substrate, where they join with at least one connection element of the SiP. The apparatus may further comprise one or more heat sinks, and may further comprise one or more temperature measurement location markings on the packaging of the SiP.

According to some embodiments, a SiP comprises: a first active device; a second active device; and a packaging covering the first and second active devices, where an outer surface of the packaging comprises a location indication for thermal measurement. In certain aspects, the location indication may be provided in the location of the second active device.

According to embodiments, a method for manufacturing a SiP is provided that comprises: selecting a plurality of active components for a SiP, wherein each component has a corresponding thermal parameter or operational thermal characteristic; mounting and operatively interconnecting the components based on the thermal parameters or operational thermal characteristics; and encapsulating the substrate and mounted components with an encapsulant to form a packaged SiP. The method may be, for example, a method for designing and/or manufacturing a SiP according to the embodiments described above.

These and other features of the disclosure will become apparent to those skilled in the art from the following detailed description of the disclosure, taken together with the accompanying drawings.

### BRIEF DESCRIPTION OF THE DRAWINGS

FIGS. 1A and 1B depict an integrated circuit mounted on a substrate.

FIGS. 2A, 2B, 2C, 2D, 2E and 2F depict SiP devices according to embodiments.

FIGS. 3A, 3B and 3C depict SiP devices according to embodiments.

FIGS. 4A and 4B depict SiP devices according to embodiments.

FIGS. 5A, 5B and 5C are flow charts illustrating methods according to embodiments.

FIGS. 6A, 6B, 6C and 6D depict aspects of SiP devices according to embodiments.

### DETAILED DESCRIPTION

System in a Package (SiP) solutions can combine multiple functional components and devices in a single package. These SiPs may be either entirely customized for a specific function or purpose, or they may be general-purpose building blocks (smart blocks) around which other additional specific components may be added for a specific application. However, existing SiP designs fail to fully address thermal management of components in the SiP. With multiple integrated circuits placed together on a small substrate, with each one having different thermal and operational requirements and different thermal footprints, the proper component placement, the design, packaging and the thermal management of the overall SiP and its package thermal characteristics should be handled interactively to assure optimal thermal and electrical performance of the SiP.

The present disclosure allows for a unified design process that includes providing desired thermal performance. While aspects of this disclosure address thermal issues having to do with heat generation and dissipation, embodiments may also be used to increase the operational temperature range at low temperatures rather than at high temperatures. This may be, for example, by using thermal management methods to increase the temperature range over which a SiP device may be safely operated to include both higher and lower temperature ranges.

According to some embodiments, separating devices with high thermal characteristics such as, but not limited to, temperature, heat generation, and power dissipation, from those with lower thermal characteristics on the SIP, and using the differences between the two resulting temperatures and amount of heat generation, may be exploited to convert their thermal differences into a different form of energy, such as for example, electrical or mechanical energy. In some embodiments, a heat sink (e.g., slug) may be employed as one of the lower thermal capacity devices. A heat sink may be used to not only conduct heat away from the SiP component(s) generating heat, but also to convert the heat differentials into another kind of energy.

Additionally, a relatively hotter device may be used to warm a relatively cooler device for the SiP to be functional at the low end of an operational temperature specification. This could include, for example, extending the lower working temperature of a SiP device to below −40 C.

Some embodiments determine and/or identify the correct location (or locations) on the surface of a packaged SiP device to properly measure the case temperature of the SiP. Depending on the components integrated into the SiP, there may be more than one location to measure case temperature in order to thermally manage more than one thermal domain on the SIP. As there may be multiple devices that have different operating and thermal characteristics mounted on a SiP substrate in a packaged SiP device, it may be important to select one or more locations for determining minimum and maximum SiP package functional temperature specifications. By doing so, a case temperature specification may be determined that maximizes the functional operational temperature range of the SiP rather than being limited by a specific component within the SiP. Similarly, a SIP's absolute maximum temperature range may be better defined based on the operational temperature ranges for the components used in the SiP.

Some embodiments allow for a larger heat sink to be used in thermal management by placing the higher temperature generating components with other higher temperature generating components and surrounding these higher temperature generating components with devices more tolerant of high temperature, which surround and partially isolate the higher temperature generating components from those components with lower temperature tolerances. Further, surrounding the higher temperature generating components with high temperature tolerant components acts as a heat barrier further separating the lower temperature tolerant devices from the high temperature components. Examples of high tolerant components include qualified automotive grade (X7R) components with an operational −55 to +125 C temperature range, as compared to an industrial grade (X5R) component with an operational −55 to +85 C temperature range.

Other embodiments allow for the extraction (or conduction) of heat away from the SiP while impeding the heat from spreading to other components in the SiP. For example, allowing the heat to dissipate through the top or bottom surface of the SiP while preventing the heat from spreading to other components by eliminating heat conductive paths from the source of the heat to the other components attached to the surface of their common substrate (or the multiple substrates included in the SiP).

The temperature of a device during operation in a system is an important parameter as it affects many properties, such as, for example, device functionality, reliability, and lifetime. Since a SiP may contain multiple ICs and passive devices, single IC package data alone should not be used to estimate the SiP's thermal characteristics in certain aspects. Accordingly, and according to some embodiments, it is desirable to configure a SiP and its substrate and various components in a manner that takes into consideration the thermal management of the overall thermal behavior of the SiP based on the thermal characteristics of its substrate and various components.

Thermal management can refer, for example, to managing heat generated by components mounted on the substrate of a packaged SiP during operation from adversely affecting the operation of adjacent components. It can also refer to managing the operational temperature range of a packaged SiP, for instance, to increase the temperature range of the SiP, and isolate components with different thermal and temperature characteristics from each other.

The following disclosure provides many different embodiments, or representative examples, for implementing features of the disclosed subject matter. In addition, the present disclosure uses the same reference numerals (or item numbers) in the various examples and figures, for purposes of clarity and simplicity, to represent the same component.

Electronic components are typically made commercially available with different allowable operating temperature ranges based on a “grade.” Common temperature ranges are, for example: (i) “commercial grade” (0 C to +85 C), (ii) “industrial grade” (−40 C to +85 C) and (iii) “automotive grade” (−40 to either +105 C or +125 C). In active circuits there is generally a relationship between performance, as in clock speed, and resulting operating temperature or power generation and dissipation. Specifically, the performance is typically reduced as the operating temperature increases. Also, the power dissipation (or thermal energy) goes up as either the performance or operating temperature increases. But many passive devices, particularly resistors and inductors, are specified to meet automotive temperature requirements, and in the case of resistors, many exceed the temperature range of corresponding active circuits (e.g., −55 C to +155 C).

Active circuits such as processors and power management devices (PMICs) may work over a wider temperature range without a compromise in performance as the temperature rises, while active circuits such as memories are more sensitive to higher temperatures and may become inoperative at temperatures at which the microprocessors and PMICs are still capable of working. Thus, when integrated into a SiP device some care must be taken, first, in the selection of the components and second, in their placement on the substrate to assure that the active and passive circuits are functioning optimally over the temperature range specified for the SiP. The expected operational temperature range for a SiP can determine the grade of the components used to manufacture that SiP (such as “commercial”, “industrial”, “automotive”, “oil and gas”, “military”, or “outer space”). The term operational can describe the ability of the devices in the SiP to effectively function together. This is generally based on the temperature of the devices. Thermal management may include removing (or using) the heat generated by the components such that they remain within their specified operating temperature range. The data sheet associated with a device typically identifies specified temperature operating ranges, that is, the range of temperatures in which the component functions according to its data sheet.

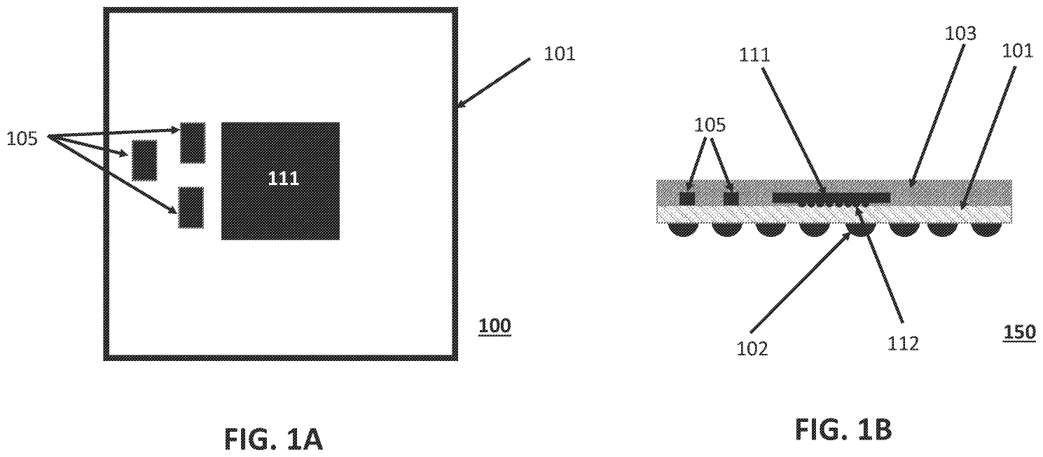

FIGS. 1A and 1B show two views of examples 100, 150 of an integrated circuit 111 mounted on a substrate 101 with a ball grid array 102 attached to the non-packaged back side (or under-side) of a substrate for making external interconnections with the integrated circuit 111. In this example, the actual die of the integrated circuit is either mounted on a substrate with bond pads on its top surface and electrically interconnected to the substrate with bond wires (not shown), or is mounted with the bond pads electrically connected directly to the substrate using a flip chip methodology 112, or other mounting methods and techniques. In some packaged systems 100, passive components 105 may be used to condition the input and output signals generated by the integrated circuit 111. The substrate can have vias and conductive traces in various spaced apart layers to get the connections for components on the top surface of the substrate to the interconnection means (ball grid array, pins, etc.) on the bottom surface of the substrate. Heat generated by the integrated circuit 111 is then conducted away through either a ball grid array 102, or through the encapsulant 103 on the top side of the packaged device using (but not shown) heat sinks, cooling fans, or other heat removal mechanisms.

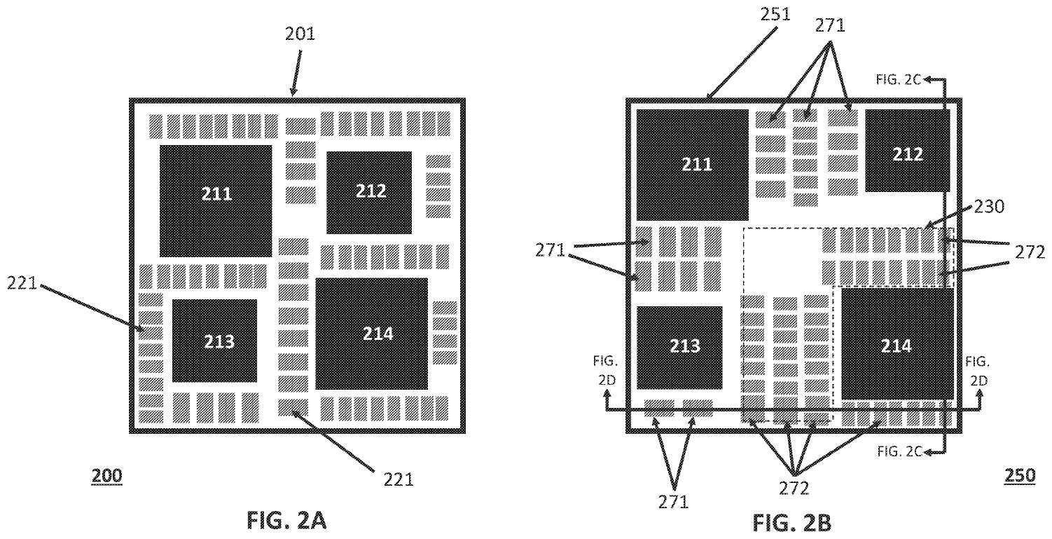

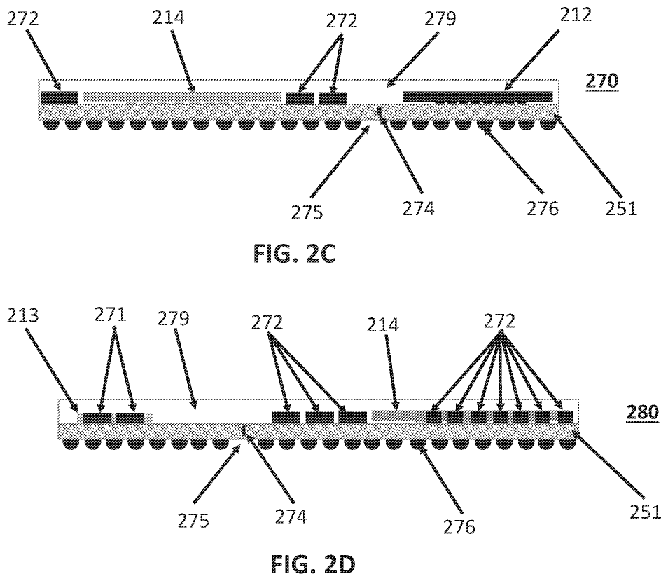

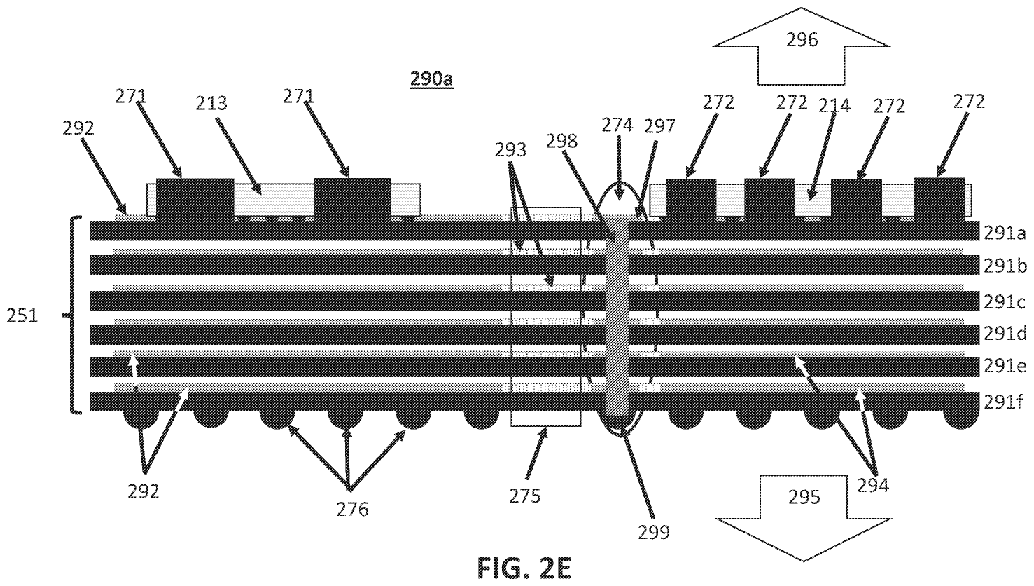

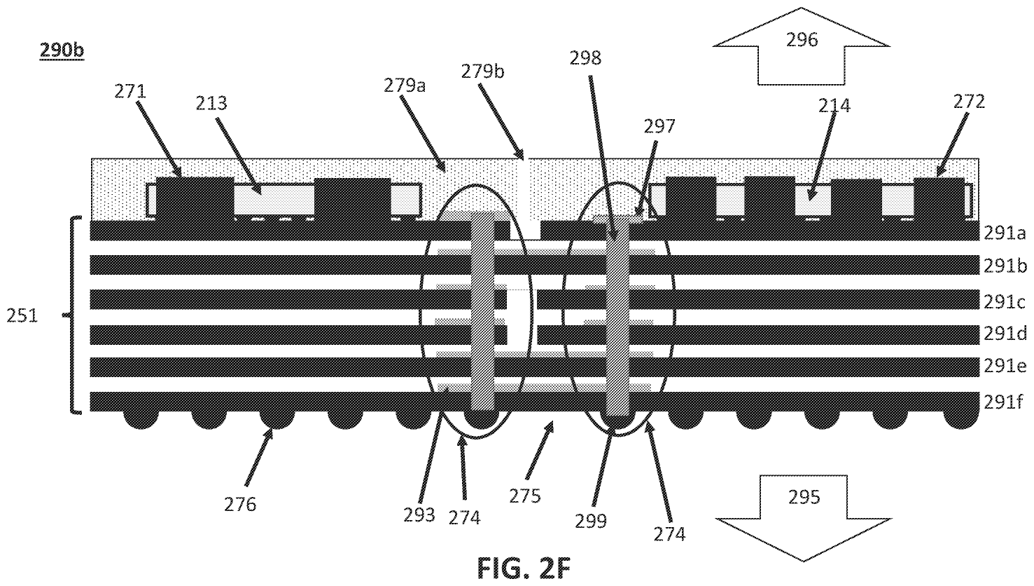

FIGS. 2A, 2B, 2C, 2D, 2E, and 2F depict SiP layouts according to some embodiments. In certain aspects, FIG. 2A depicts the footprint of a SiP without considerations for thermal management, and FIGS. 2B, 2C, and 2D depict different views of the footprint of a SiP constructed with considerations for thermal management. In other words, in the example of FIG. 2A the components in the SiP are assumed to have the same or similar thermal and temperature characteristics (or their characteristics are ignored), and are not purposefully selected based on their thermal characteristics. Whereas in FIGS. 2B, 2C, and 2D there are multiple variations of thermal and temperature characteristics for components in the SiP, and which regions or areas are made on the SiP substrate for components with similar thermal and/or temperature characteristics. FIGS. 2A, 2B, 2C, 2D, 2E, and 2F depict the same active devices represented as four integrated circuits (ICs) 211-214 surrounded by a number of passive components (221, 271 and 272) such as, for example, but not limited to resistors, capacitors and inductors, needed for correct electrical operation of the SiP in accordance with the SiP design. In general, although passive components typically do not generate significant thermal energy during operation, they may generate low levels of thermal energy during operation. The SiP 200 of FIG. 2A and the SiP 250 of FIGS. 2B, 2C, 2D, 2E, and 2F may have an array of balls on its back side (shown in FIGS. 2C, 2D, 2E, and 2F) for external connections, but may also have pins attached to the substrate in various ways for external connections.

In the examples of FIGS. 2A, 2B, 2C, 2D, 2E, and 2F, integrated circuit (IC) 214 generates significantly more heat during normal operation than the other three ICs 211-213. Further, all the other components (e.g., 221 in the SiP layout of FIG. 2A) may have the same or a different specified operational temperature ranges as IC 214, while in FIGS. 2B, 2C, 2D, 2E, and 2F the other components may have two or more operational temperature ranges. For instance, passives 272, which at least partially surround IC 214, may have a higher specified operating temperature range when compared to the operating temperature ranges of other components 271 adjacent the other three ICs 211, 212 and 213. In some embodiments, each of the various ICs will have different amounts of power generation and dissipation depending upon its function. Thus, the thermal and operational behavior of the SiP becomes complex as the power generation and dissipation among the different components in the SiP is not considered during the design and when there is no thermal management.

In the examples of FIGS. 2B, 2C, 2D, 2E, and 2F, there are two mechanisms involved in the selection of the passive components: (1) using other components (e.g., 271 and 272) as one way to maximize the physical isolation of the active devices generating heat, and (2) taking advantage of a greater temperature range for those components (e.g., 272) surrounding the hotter device (e.g., 214).

With further reference to FIG. 2A, in a SiP 200, the integrated circuits 211-214 are arranged with all the components 221 such that different physical sizes and thermal characteristics are placed on the substrate 201 around the integrated circuits, 211-214, with consideration of electrical interconnections. Absent thermal management considerations, all the integrated circuits and other components are assumed to have similar operational temperature ranges based upon the expected operating temperature of the SiP; heat generation capacity and dissipations are minimally considered limited attention to the thermal interactions among the components.

FIGS. 2B, 2C, and 2D depict an example of a different layout for the same set of components depicted in FIG. 2A, but mounted on a different substrate 251 that is the same size as substrate 201 in FIG. 2A. FIG. 2B depicts a top view, and FIGS. 2C and 2D depict two different side views of the FIG. 2B embodiment, using examples of the same components having the same electrical values as shown in FIG. 2A, for instance. That is, the functional SiP design for these four device layouts is the same and accordingly, the electrical values of the components in all four figures is the same, even though they are arranged differently between FIG. 2A and FIGS. 2B, 2C, and 2D. In this embodiment, the substrate 251 has been laid out with an understanding of the thermal characteristics such as, but not limited to, the operational temperature ranges, and heat generation and dissipations for each of the components. These components comprise, for example, the integrated circuits 211-214, other components 271, 272, the substrate 251, and the external connectors of the package. With an understanding of the thermal characteristics of each component, the layout (footprint) is altered to manage the thermal characteristics of the SiP, and accordingly minimize any undesired thermal interactions between components and thereby avoid thermally adverse interaction between and among active and passive components where excessive temperature and thermal characteristics of one component adversely affects the operation of another nearby or adjacent component.

According to embodiments, strategies may be employed for thermal management in FIGS. 2B, 2C, and 2D. In a first example, the three ICs with the lower allowable operating temperature range and lower heat generation and dissipation 211-213 are moved away from the IC with the highest allowable operating temperature range and highest heat generation and dissipation 214. FIG. 2B depicts how the four ICs are spread apart and located in the corners of the substrate. This isolates IC 214 from the rest of the active components, allowing it (IC 214) to be thermally managed differently from the rest of the ICs (211, 212, 213) and other components with lower operating temperature ranges 271. Also, by surrounding the highest heat generating and dissipation IC 214 with other components 272 which are similarly designed with greater temperature ranges, the SiP has better performance by making sure the surrounding components 272 of the IC 214 withstand exposure to higher temperatures, while serving as a thermal barrier 230 to help isolate the high heat dissipation device 214 from affecting the other components with lower operating temperature ranges. This same method of isolation may be used for multiple devices with variations of higher or lower temperatures.

The examples depicted in FIGS. 2B, 2C, and 2D may be described in further detail where device 214 is an example microprocessor that generates the largest amount of thermal energy on the substrate. Further, the thermal energy generated by device 214 increases as the performance (clock speed) of the microprocessor increases. This illustrates the coupling of operational parameters with a component's thermal parameters. Further, device 214 may have an operating temperature specification of −40 C to +125 C. Next, device 213 is an example memory device, which generates less thermal energy than the microprocessor 214 and has an operating temperature range of −40 C to +85 C. Device 212 is an example power management integrated circuit (PMIC), which also generates less thermal energy than the microprocessor 214 in this example, but perhaps more thermal energy than the memory 213. Device 212, as with microprocessor 214, has a similar temperature range specified, but perhaps generates less thermal energy in this example. Finally, device 211 is an example I/O device with similar thermal characteristics as memory device 213. According to embodiments, the components are of the same grade. In some embodiments, components of different grades may be used.

Surrounding the microprocessor 214 are passive devices 272 such as, for example, capacitors, resistors, inductors, thermally insolation devices, and other components, which have operating temperature ranges equal to or better than the microprocessor 214. The other three devices 211, 212, and 213 of this example are surrounded by passive devices 271, which have thermal and temperature characteristics compatible with each of the devices but may not have operating temperature ranges which match those of microprocessor 214. The active and passive components are then placed on the substrate in four different physical areas, or thermal domains, where the microprocessor 214 and its thermally compatible passive devices 272 are in one thermal domain, while the memory 213, PMIC 212 and I/O device 211 along with their respective compatible temperature range passive components 271 make up the other three thermal domains. Each of the four individual thermal domains may now be uniquely and separately managed. Or, in some cases, one or more of the thermal domains may be treated together as one thermal domain.

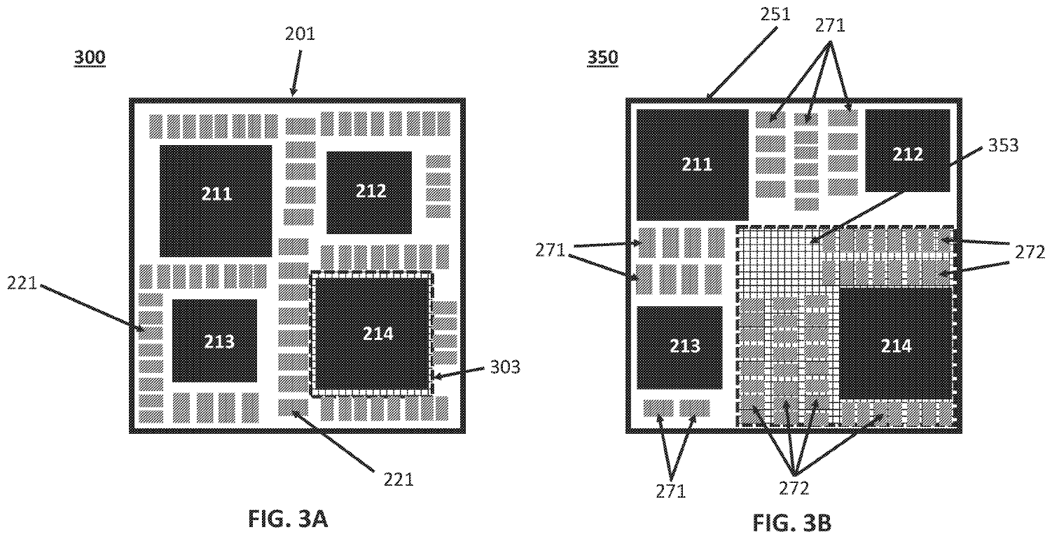

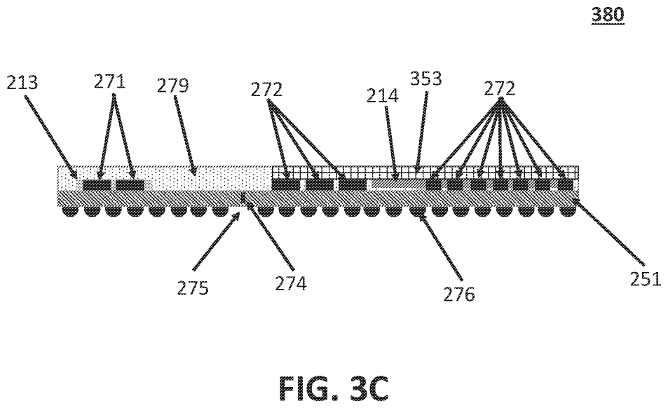

Each thermal domain may then be managed by techniques such as, for example, heatsinks (see FIG. 3B), thermal barriers, an arrangement of vias 274 (see FIGS. 2C and 2D) or conductive traces included in the substrate, non-conductive regions in the substrate, and physical isolation. Vias 274 and conductive traces may be included as shown, for instance, in FIG. 2E, in the substrate to conduct heat to either a heat sink or to the external connectors 276 and non-conductive regions in the substrate may be employed to stop the conduction of heat to other areas, such as for example, for removal of conductive traces in the substrate or the elimination of selected external connectors 275 (see FIGS. 2C and 2D).

Although FIG. 2B and other figures depict the four thermal domains to be side by side on the surface of the substrate, the domains may also be stacked above each other on the surface of the substrate, or using different substrates, or stacked on each other. The same concepts of separating thermally compatible components into thermal domains and managing each thermal domain in the stack can be the same as those arranged side by side. For example, thermal barriers may be implemented in a vertical arraignment between devices on different layers or planes within the SiP. Finally, a combination of some of the thermal domains being side by side and some being stacked, or in some cases thermal domains also placed on the other side of the substrate may be employed to isolate and manage the various thermal domains according to embodiments.

Referring now to FIG. 2E, a detailed view 290a of one or more portions of FIG. 2D is provided as an example of a thermal management technique that minimizes heat flow in the horizontal axis (from one component to another) of the SiP while allowing to heat flow in the vertical axis, either up 296 or down 295. This may be, for example, through the connection balls 276 or through the top of the package. As shown in FIG. 2D, active components 213 and 214, along with other components 271 and 272 are attached to the top surface of the substrate 251. In the example of FIG. 2E, the substrate 251 has been expanded to include six layers 291a-f, with four different regions of conductive traces 292, 293, 294, and 297 on the various layers, and external connections ball grid array (BGA) 276. Each layer of the substrate's six layers contains four different regions of conductive traces.

With further reference to FIG. 2E, in region 292, the traces are densely laid out to electrically connect to the components in that region and in other regions. Similarly, the conductive traces in region 294 are densely laid out to electrically connect the components in its region and in other regions. To minimize heat transfer between regions 292 and 294 a barrier region 275 may be created and in that region the number of traces 293 between the two regions (and other regions) may be minimized. In addition to the reduced number of traces in the barrier region 275, one or more of the connection balls on the bottom of the substrate that make up the BGA 276 may be omitted. A thermal barrier region 274 may be created by an array of vias 298 surrounding and between the regions 292 and 294 traversing the substrate and attaching to barrier traces 297 on each substrate layer. Finally, an array of balls 299 (one or more) in the array may be attached to, and in thermal contact with, the array of vias 298 to complete an alternative thermal barrier. According to some embodiments, however, the vias do not connect all the way to the connection balls.

FIG. 2F depicts another detailed view 290b of one or more portions of FIG. 2D as different examples of a thermal management technique that minimizes heat flow in the horizontal axis of the SiP, while allowing heat to flow in the vertical axis, similar to the flows depicted in FIG. 2E. FIG. 2F depicts the same or similar components as in FIG. 2E, but employs physical gaps between certain layers of the substrate to further impede horizontal heat flow and a series of vias that are interconnected with a conductive trace to conduct heat downward in a manner similar to the via of FIG. 2E. In certain aspects, one or more of the vias can be slightly offset from the one immediately above it. FIG. 2F also depicts a physical separation 279b of the mold compound 279a that encloses the components and substrate to separate the thermal regions while forming the packaged SiP device.

Accordingly, embodiments can provide thermal management for a SiP containing a plurality of components having different operational and thermal characteristics that affect the temperature and operational performance of each of the plurality of components. In certain aspects, thermal management of a SiP may at least involve ensuring that the components generating more amounts of power that may be dissipated and impact the operation of adjacent components in a negative manner are thermally isolated to prevent such negative impact.

FIGS. 3A, 3B, and 3C depict System in a Package (SiP) layouts 300, 350, and 380 according to some embodiments. The example of FIG. 3A has a small area for a heatsink (303) or slug, while the examples of FIGS. 3B and 3C have a large area for a heatsink (353) or slug.

FIG. 3A depicts a device 300 with the area available 303 for a heat slug to cover the high heat dissipation IC 214 in a first layout. In this example, it is restricted to the area above (or below) the heat dissipating IC 214 and may extend to the other surrounding components 221, but not overlap them as they may not be specified for the higher operating temperature of the IC 214. FIGS. 3B and 3C depict devices 350, 380 with a larger area available 353 for a heat slug to cover (e.g., above or below) the high heat dissipation IC 214. In this example, because the other surrounding components 272 have a higher operating temperature range, they will be able to reliably handle the higher temperature resulting from the high heat dissipation IC 214. The larger area is made possible by the higher temperatures specified for the other components 272 which surround the hotter IC 214. In this case the heatsink 353 is larger than that in FIG. 3A (303). In some embodiments, an additional and thermally separate heat sink may be used, for instance, above or under one or more of devices 211, 212, and/or 213.

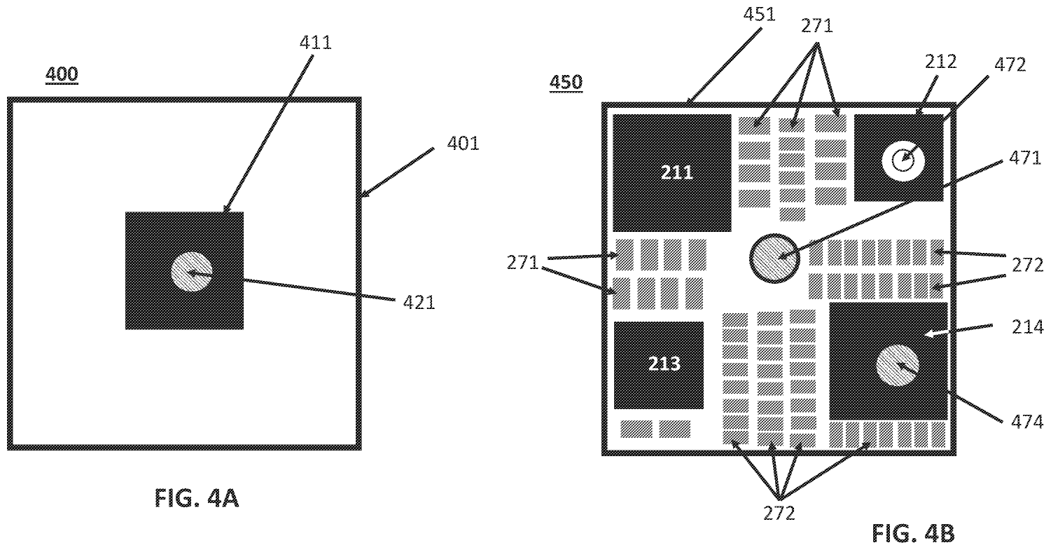

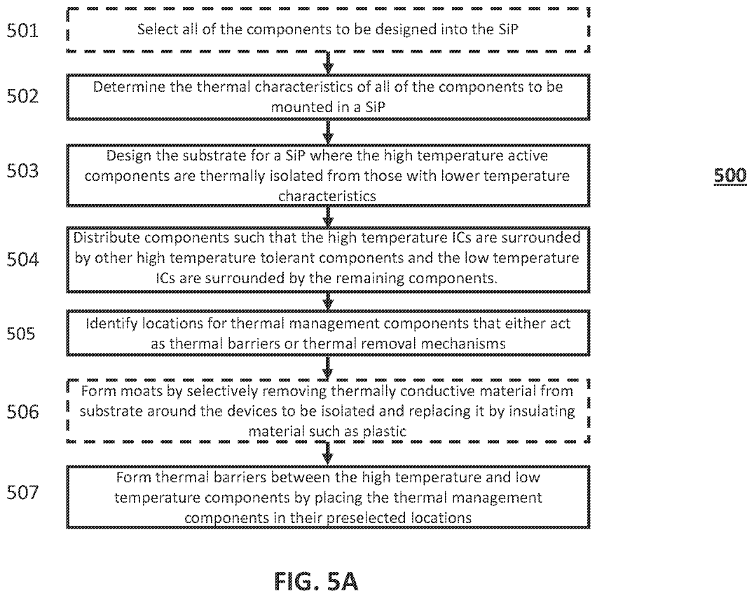

FIGS. 4A and 4B depict locations to measure the case temperature of a packaged SiP device 400, 450 according to embodiments. While the examples of FIGS. 4A and 4B are marked with a circular indication, other markers may be used, such as an “x”, symbol, company logo, or other shape or text. The markings may be located, for instance, on an exterior of the SiP device (e.g., on a top surface of the package).

FIG. 4A depicts one area 421 for temperature measurement to determine the case temperature of a packaged device 401. In existing systems, it is typically not marked on the package exterior. Because it is common for an integrated circuit to have the active component 411 placed in the center of the package 401, area 421 is central. As the active component 411 is the major source of any heat generated, the temperature measurement can be taken in an area 421 over the active component 411. The maximum case temperature of the device is specified by the vendor who manufactures the component. To exceed the maximum case temperature, and sometimes to exceed the minimum case temperature (i.e., operate below the minimal temperature specification, for example at −100 C), may result in component failure. With thermal management according to embodiments, both the higher temperature specification limit and/or lower temperature specification (operational and/or absolute) limits may be extended. In some cases where the SiP is to function below the low temperature limit, an additional component may be added to assure the active devices are within their temperature limits prior to being powered on. This may also be a solution to bring the temperature down below the upper temperature limit using some cooling method such as, for example, a cooling device, or other known thermal removal techniques.

FIG. 4B depicts a system in package (SiP) device 450 according to embodiments where there are four active components 211, 212, 213, 214. According to embodiments, a number of these active components will have unique thermal characteristics and operational temperature ranges along with different functional characteristics resulting from an increased operating temperature. For example, the active component 212 may be at a lower temperature than the active component 214 operating in the same package 451 at the same time. Accordingly, the maximum safe operating temperature of active component 212 may be specified to be much lower than that of active component 214. The packaging 451 may comprise, for instance, an encapsulant as described with respect to FIGS. 2B-2F.

In certain aspects, the active component 214, although capable of and normally operating at a higher temperature than IC 212, may also have a higher maximum operational temperature specification than IC 212 in this example. Whereas the active component 212, although having a lower actual temperature, may have a much lower maximum temperature specification and lower operational temperature range. Where to measure the SiP package temperature to allow for optimal functionality of the SiP device 450 may thus be dependent on the location of the measurement related to the component inside the SiP package over which that location is positioned. In the example of FIG. 4B, if the SiP package temperature is measured in the center of the SiP package 471, it will not reflect the operating temperature of either active component 212 or 214. If the SiP package temperature is taken above the active component 214, at location 474, when it reaches the maximum specified case temperature of the SiP, the temperature of the other active circuit 212 will be operating well below its maximum operating temperature. Finally, taking the temperature measurement at location 472 over the active component 412, the most temperature sensitive component on the SiP may better determine the best package temperature of the SIP. A temperature difference between a component within the SiP and the temperature measured on the exterior of the SiP package is assumed to be 20 degrees C. for these examples. Different temperatures and variations may be used.

In embodiments, active component 212 may be a synchronous DRAM (DRAM) whose steady state operating temperature is 20 degrees Celsius (20 C) above room temperature, typically at ambient (25 C), while the active component 214 may be a microprocessor (uP) whose operating temperature is 40 C above ambient. If the maximum operating temperature specified for the DRAM 212 is an 85 C case temperature, while the maximum operating temperature of the uP 214 is a 125 C case temperature, then if the package temperature of the SiP 450 is measured at location 474 over the uP 214 with a specification of a maximum 85 C the operating temperature of the DRAM at the specified case temperature will only be 65 C, still well below its maximum operating temperature specification. If the case temperature is measured at location 472 above the DRAM 212, when it is measured to be at the 85 C maximum specification, the uP 214 will be at a temperature of 105 C, well within its maximum rating of 125 C. This could mean that the SiP 450 will be able to operate at a case temperature 20 C higher than when measured at location 474 above the uP 214, while still within the specified maximum case temperature of 85 C. For DRAM, one or more locations may be monitored for case temperature such as both 472 and 474. By taking measurements from multiple locations more sophisticated thermal management such as, but not limited to, clock frequency management, or fan speed control, may be used.

Some embodiments provide temperature measurement points on the exterior of the SiP package containing a plurality of components having different operational and thermal characteristics that affect the temperature and operational performance of each of the plurality of components to ensure that the components generating more amounts of power that may be dissipated and impact the operation of adjacent components in a negative manner are appropriately monitored for operating temperature.

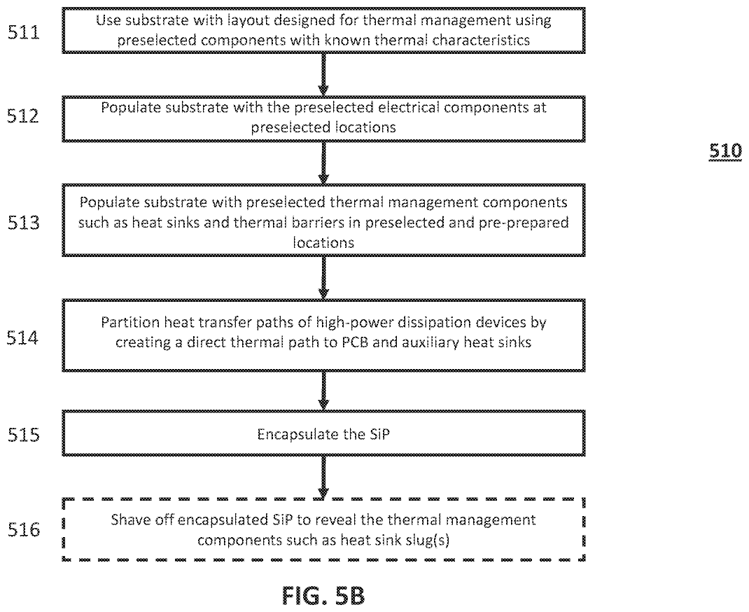

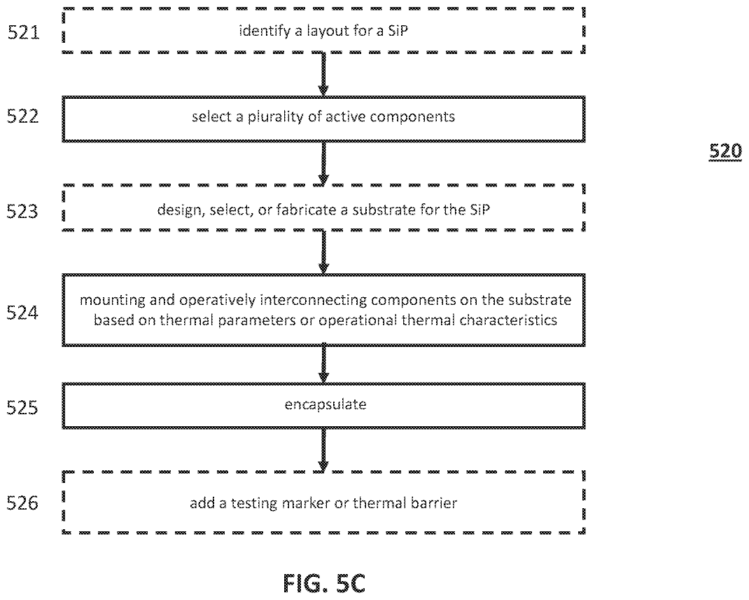

FIGS. 5A and 5B depict methods for optimizing the design and assembly of a SiP's substrate and/or layout with considerations for thermal management according to embodiments. For example, the methods may be used for designing and manufacturing a thermally optimized and managed SiP. In certain aspects, the methods may be applied, for instance, in connection with devices shown with respect to FIGS. 2B, 2C, 2D, 2E, 2F, 3B, 3C, and 4B.

FIG. 5A depicts a method 500 for designing (e.g., laying out or otherwise arranging) a SiP or SiP substrate with considerations for thermal management according to embodiments. In some embodiments, the first step to the process is to select 501 all the components to be designed into a SiP, for example, into the SiP 250 of FIG. 2B. This may require selecting the components based on their temperature specification as needed to optimize the thermal footprint of the substrate based on the expected operating temperature range for the SiP design. In some embodiments, this step is optional. Once the thermal characteristics are determined 502 for each component to be placed on the substrate, the substrate may be designed 503 (e.g., laid out) so that the IC(s) and passive devices may be placed on the substrate in such a way as to isolate the IC(s) with the highest heat generation and dissipation from the other IC(s) and other components. This may include generating areas of the substrate that are thermally isolated from each other. This isolation may be accomplished by creating moats by removing thermally conductive material from the substrate around the devices to be thermally isolated, and (optionally) replacing the removed material with insulating material, such as for example, but not limited to plastic. The high heat generation and dissipation ICs may be surrounded/isolated with other components with higher temperature range specifications and then populating 504 the other components with lower temperature range specifications away from the highest dissipating IC(s) in other thermally isolated areas of the substrate. Locations may then be identified 505 for thermal management components, which either act as thermal barriers or thermal removal mechanisms 506. Use of removal regions may be optional in some embodiments. Thermal barriers may then be created 507 between the high temperature and low temperature components by placing the thermal management components in their preselected locations. According to embodiments, one or more steps of FIG. 5A may be optional in some implementations.

FIG. 5B depicts a method 510 for manufacturing a thermally managed SiP according to embodiments. In some embodiments, the method may begin by selecting a substrate 511 using considerations for thermal management as part of its design (e.g., as part of its layout or configuration), and using preselected components with known thermal characteristics, such as for example, but not limited to that specified in FIG. 5A. Next, the substrate is populated 512 with the preselected electrical components at their preselected locations. The substrate is then populated 513 with preselected thermal management components such as heat sinks and thermal barriers in their preselected locations. Next, partitioning the heat transfer path of high-power devices is performed 514 by creating a direct thermal path to a PC board or to auxiliary heat sinks. The SiP is then encapsulated 515. Finally, if necessary, step 516 includes shaving off a portion of the encapsulated SiP to reveal the thermal management components such as heat sink(s). In embodiments, managing the temperatures of a single component within a SiP may be used to control the overall temperature of the SiP, if controlling the temperature of the single component does not adversely affect the operations or temperatures of other adjacent or nearby components within the SiP. Further, such control of the SiP temperature may be provided by any internal or exterior type of microcontroller or microprocessor suitably programmed. According to embodiments, one or more steps of FIG. 5B may be optional in some implementations.

Referring now to FIG. 5C, a method 520 is provided according to some embodiments. The method may be used, for instance, to design and/or fabricate a SiP according to any of FIGS. 2B, 2C, 2D, 2E, 2F, 3B, 3C, and 4B. The method may begin with step 521, which may be optional in some embodiments, in which a SiP layout is identified. In step 522, a plurality of active components (e.g., 211, 212, 213, 214) are selected. In step 523, which may be optional in some embodiments, the substrate is designed, selected, fabricated, or otherwise obtained. In some embodiments, the substrate of step 523 is a substrate as illustrated in FIG. 2E or 2F. In step 524, the components are mounted and interconnected. This step may comprise, for instance, forming the arrangement of components shown in any of FIGS. 2B, 2C, 2D, 2E, 2F, 3B, 3C, and 4B. In step 525, the components are encapsulated. In step 526, which may be optional in some embodiments, a testing marker or thermal barrier is built into the device. This could include, for instance, a marker 472 as shown in FIG. 4B or a thermal barrier as described in connection with any of FIGS. 2B, 2C, 2D, 2E, 2F, 3B, 3C, and 4B.

Depending on the system, it may be necessary to keep some of the active device(s) powered down until a steady state temperature is obtained so those circuits can safely be powered up. This may be important when the SiP's operating temperature range exceeds the component's temperature range, either below the minimum temperature or above the maximum temperature. The thermal management of the SiP therefore may be a part of the SiP's processor algorithm or may be managed by an external controller element in the larger system containing the SiP. Both cooling devices and/or heating devices may be employed either external to the SiP or integrated into the SiP as one of its components. These cooling and heating devices may be integrated into the substrate, on one or both sides of the substrate or integrated into a component stack on the substrate.

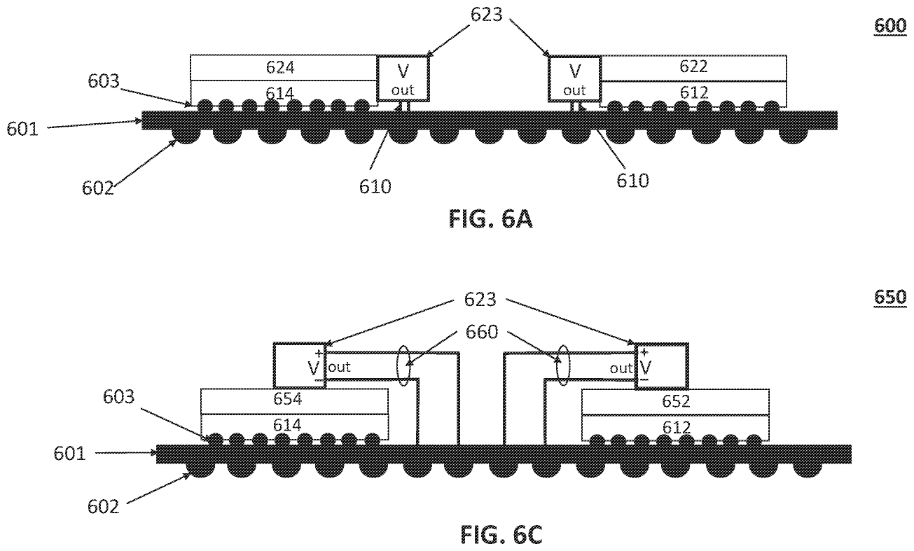

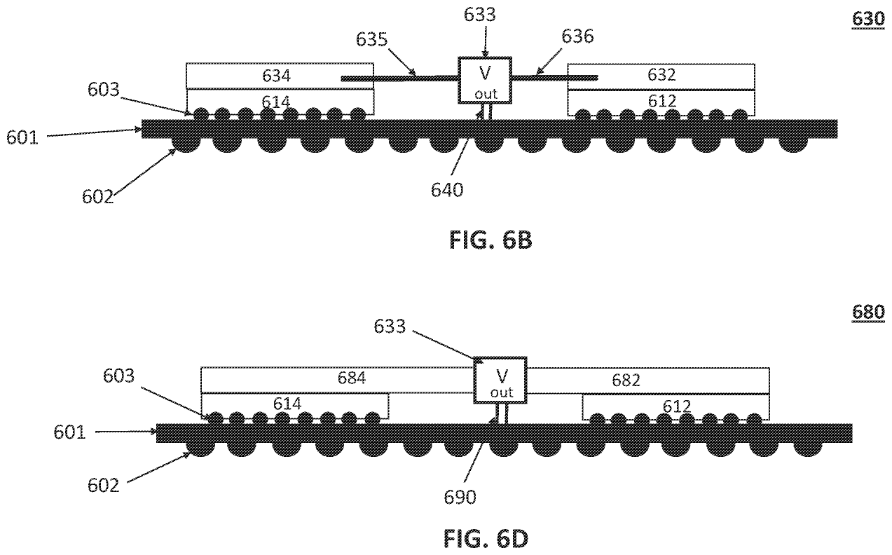

FIGS. 6A and 6C depict the use of thermoelectric converters directly connected to heat sources in the SiPs 600, 650 according to some embodiments. In FIG. 6A, the thermoelectric converters 623 are connected to each device 614 and 612 and/or their respective heat sinks 624 and 622. The output voltages 610 of each of the thermoelectric converters 623 are connected to the appropriate voltage rail(s) available in or on the substrate. The substrate may include special voltage rails suitable for receiving the output voltage(s) of the thermoelectric converters 623 and interconnected with circuitry for managing or using those voltage(s), which may be for example, a PMIC, a sensor, or other voltage storing and conditioning circuitry. For FIGS. 6A and 6C, a thermoelectric converter 623 may be for example, a thermocouple or semiconductor device. In FIG. 6C, the thermoelectric converters 623 are connected to the each of the heat sinks 654 and 652. The output voltages 660 of each of the thermoelectric converters 623 are connected to the appropriate substrate voltage rails. Alternatively, each of the thermoelectric converters 623 may be attached directly to the devices 614 and 612 when a heat sink is not needed.

FIGS. 6B and 6D depict a device 630, 680 for converting a temperature difference between two devices to an output electrical voltage and current according to some embodiments. In each of FIGS. 6B and 6D, there are two devices 614 and 612 attached to a substrate 601 through leads 603. The substrate 601 has other connection leads 602 to connect the SiP to external destinations. According to embodiments, one device 614 is hotter than the other device 612 creating a temperature difference between the two devices. In certain aspects, FIG. 6B depicts the use of thermal conductors 635 and 636 (e.g., heat pipes) to conduct the heat from the two heat sinks 634 and 632 of devices 614 and 612, respectively, to a thermoelectric converter 633. The output electrical power 640 generated by the thermoelectric converter 633 is connected to the appropriate substrate voltage rail (not shown). Alternative construction may eliminate one or both of heat sinks 634 and 632. In this construction, the thermal conductors 635 and 636 may be attached directly to the devices 614 and/or 612. In certain aspects, FIG. 6D depicts a direct connection from the heat sinks 684 and 682 of the two devices 614 and 612, respectively, to a thermoelectric converter 683. Thermal conductivity from the source devices 612, 614 to the thermoelectric converter 683 can either be done by extending the heat sinks 682, 684 or by some other method such as, for example, heat pipes in some embodiments. The output voltage 690 of the thermoelectric converter is connected to the appropriate substrate voltage rail (not shown).

In certain aspects, for FIGS. 6B and 6D, the substrate may include special voltage rails suitable for receiving the output voltage(s) of the thermoelectric converters 633 and interconnected with circuitry for managing or using those voltage(s), which may be for example, a PMIC, a sensor, or other voltage storing and conditioning circuitry. For FIGS. 6B and 6D, the thermoelectric converters 633 may be for example, a thermocouple or semiconductor device. A combination of devices depicted in FIGS. 6B and 6D is possible with the use of a thermal conductor (635 or 636) to conduct the heat from a device which has no heat sink. Finally, the thermoelectric converters 633 may include circuitry to receive the electrical energy generated by the thermal conversion and accumulate the energy until it has reached a charge large enough to perform predetermined operation such as, for example, a sensor providing an output, an actuator, or an output signal.

Embodiments may be used to generate electrical energy from temperature differences in a SiP package containing a plurality of components having different operational and thermal characteristics that affect the temperature and operational performance of each of the plurality of components.

According to embodiments, the arrangement of FIG. 6D may be used to “pipe” the heat from a warmer device 614 to a cooler device 612, as part of warming up the interior of a SiP before powering up the remaining devices in the SiP, when the SiP is exposed to temperatures that are below the recommended operating temperatures of some of the components of the SiP. For this type of application, the device 633 becomes a heat exchanger and may be controlled for use in such low temperature SiP operations to control the heat transfer and be controlled to prevent such heat transfer for other operations.

According to embodiments, the devices and techniques described with FIGS. 6A, 6B, 6C, and 6D may be combined with the embodiments of FIGS. 2B, 2C, 2D, 2E, 2F, 3B, 4B, 5A, 5B, and 5C. That is, the thermoelectric aspects may be part of larger thermal design or management as described herein.

According to embodiments, thermal management is provided for a System in a Package (SiP) containing a plurality of components having different operational and thermal characteristics that affect the temperature and operational performance of each of the plurality of components by moving thermal energy (temperature) from hotter components to cooler components in the SiP. Thermal management of a SiP may involve moving thermal energy around inside the SiP to warm cooler components before they are powered up.

According to embodiments, a packaged SiP is provided, comprising: a substrate having vias and traces; a plurality of active devices/components operatively mounted on the substrate; a plurality of passive devices/components operatively mounted on the substrate; a package for embedding the substrate and active and passive devices/components, and markings on the exterior of the SiP package for measuring operating temperatures for selected devices/components in the package. The markings may be, for instance, on the top surface of the SiP package.

According to embodiments, a device is provide comprising: a substrate having vias and traces, etc., and a plurality of thermally isolated areas; and a plurality of devices/components with preselected thermal and operational characteristics for a SiP design located in the thermally isolated areas. A corresponding method may comprise operatively interconnecting the devices/components mounted on the substrate using the traces and vias of the substrate, and selecting vias and traces for thermal management.

According to embodiments, a System in a Package (SiP) comprises: a substrate comprising a plurality of layers with etched conductive paths, and a plurality of vias associated therewith for making component interconnections; a plurality of components are mounted on the substrate in thermally isolated areas and operatively interconnected using the vias and conductive paths; and the substrate and components are encapsulated to cover and protect the plurality of components are mounted on the substrate; and wherein the preselected components are mounted in areas functionally related to individual component thermal characteristics to manage the overall thermal and operational characteristics of the SiP.

According to embodiments, a method for manufacturing a packaged SiP comprises: identifying a SiP design, defining the operational temperature range(s) for the operation of the SiP design, selecting components for the SiP design in functional relationship with the operational temperature range of the SiP design, selecting at least a first set of components from the selected components having a first set of thermal and operational characteristics, designing a substrate for the SiP design having a plurality of thermally isolated areas for mounting at least one set of the selected components, mounting and operatively interconnecting the components in at least one of the plurality of thermally isolated areas based on the components thermal and operational characteristics and preselected design considerations, mounting and operatively interconnecting other components in at least one other of the plurality of thermally isolated areas based on the components thermal and operational characteristics, and encapsulating the substrate with the mounted components to form a packaged SiP.

According to an embodiments, a substrate comprises at least a first thermally isolated area and a second thermally isolated area on the surface of the substrate for mounting components. In certain aspects, isolation could also be above the substrate (e.g., encapsulant), in the substrate (e.g., vias to conduct heat from the component, selectively adding either heat conductive traces or areas of no heat conductive traces) and on the bottom side of the substrate (e.g., missing balls between thermal regions).

According to some embodiments, a substrate comprises a plurality of layers with etched conductive paths and a plurality of vias associated therewith for making operative interconnections between the pluralities of components mounted on the substrate. In some embodiments, some of the conductive layers and vias will be for electrical connections (or optical connections) and some will be used to create thermal barriers to thermally isolate the various pluralities of component groups.

In some embodiments, a thermal management device is mounted on (or adjacent or functionally operative) one or more components mounted on the substrate

Some embodiments may comprise marking one or more locations on the exterior surface of the SiP package for measuring SiP operational temperatures (case temperature), or measuring SiP temperature on one or more locations on the exterior surface of the SiP in at least a position located over a first area of the substrate of a SiP.

Some embodiments may comprise designing a SiP for maximum performance within a set of thermal operating conditions determined by the combined overall thermal characteristics of the individual components and their locations in the SiP. In certain aspects, the SiP must operate in a known set of thermal operating conditions, which can be established as part of the SiP overall design criteria based on expected operating application usage. In embodiments, the set of thermal operating conditions are determined by the thermal characteristics of each of the components and the thermal characteristics of the substrate.

In embodiments, each component operating in accordance with its design specifications (data sheet) is expected to generate a fixed amount of thermal energy and to dissipate a fixed amount of thermal energy, the dissipation of which may be modified by the component packaging or its mounting and connections with other items (like a substrate or circuit board) or system level packaging.

In some embodiments, thermal management involves designing the substrate for the components with known thermal characteristics and required for the design to operate as close as possible to its thermal constraints (like maximum operating temperature) to ensure the overall amount of thermal energy generated by components mounted on the substrate and absorbed by the components and substrate from other components does not exceed the overall amount of thermal energy dissipated by the components and substrate when all are mounted on the substrate and packaged. In certain aspects, the overall thermal energy dissipation should allow the individual components to operate at, but not exceed, their individual thermal limits.

### FURTHER EXAMPLES

A1. A System in a Package (SiP), comprising: a plurality of components having known thermal and operating characteristics (parameters), a substrate comprising a plurality of layers with etched conductive paths and a plurality of vias associated therewith for making operative interconnections between the plurality of components, and a plurality of areas on the surface of the substrate for mounting components, wherein each of the plurality of areas on the surface of the substrate for mounting components is configured/arranged for mounting a first group of components of the plurality of components having a first range of thermal and operating characteristics, wherein at least a first group of the plurality of components are operatively mounted on the substrate in one of the plurality of areas and operatively interconnected using the vias and conductive paths, wherein the substrate and components are encapsulated to cover and protect the plurality of components mounted on the substrate; and wherein the plurality of components are mounted on the substrate to optimize the thermal and operational characteristics (management) of the SiP.
A2. The SiP of example A1, wherein a second group of plurality of the plurality of components are operatively mounted on the substrate in a second one of the plurality of areas and operatively interconnected using the vias and conductive paths.
A3. The SiP of example A2, wherein a third group (or up to an Nth group) of plurality of the plurality of components are operatively mounted on the substrate in a third one (or Nth one) of the plurality of areas and operatively interconnected using the vias and conductive paths.
B1. A System in a Package (SiP), comprising: a first plurality of components having a first set of known thermal and operating characteristics (parameters) (e.g., a first grade such as automotive), a second plurality of components having a second set of known thermal and operating characteristics (parameters) (e.g., a second grade such as commercial), a substrate comprising a plurality of layers with etched conductive paths and a plurality of vias associated therewith for making operative interconnections between the pluralities of components, and a first area and a second area on the surface of the substrate for mounting components, wherein the first plurality of components are operatively mounted on the substrate in the first area and operatively interconnected using the vias and conductive paths, wherein the second plurality of components are operatively mounted on the substrate in the second area and operatively interconnected using the vias and conductive paths, wherein the substrate and components are encapsulated to cover and protect the plurality of components mounted on the substrate; and wherein the plurality of components are mounted on the substrate to optimize the thermal and operational characteristics (management) of the SiP.
B2. The SiP of example B1, further comprising a thermal management device mounted on (or adjacent or functionally operative) one or more components mounted on the substrate.
B3. The SiP of example B1 or B2, further comprising on one or more locations on the exterior surface of the SiP in at least a position located over the first area of the substrate of a SiP for measuring the SiP temperature.
B4. The SiP of any of examples B1-B3, further comprising a marking (identifier) on the exterior surface of a SiP package location(s) for measuring SiP operational temperatures.
B5. The SiP of any of examples B1-B4, wherein the first and second plurality of components are also operatively interconnected but are thermally isolated from each other.
C1. A method for manufacturing a packaged SiP, comprising: identifying a SiP design; defining the operational temperatures for the operation of the SiP design; selecting at least a first set of components for the SiP design having a first set of thermal and operational characteristics; designing a substrate for the SiP design having a plurality of areas for mounting a set of the selected components; mounting and operatively interconnecting the components in at least one of the plurality of areas based on the components thermal and operational characteristics; and encapsulating the substrate with the mounted components to form a packaged SiP.
D1. A packaged System in a Package (SiP), comprising: a substrate comprising a plurality of layers with etched conductive paths, and a plurality of vias associated therewith for making component interconnections; a plurality of components mounted on the substrate and operatively interconnected using the vias and conductive paths; wherein the substrate and components are encapsulated to cover and protect the plurality of components are mounted on the substrate, and wherein the preselected components (and/or features) are mounted in such a way as to optimize the thermal management of the SiP.
E1. A substrate design method for a thermally efficient packaged SiP, comprising: providing a circuit for the SiP; identifying components for the circuit; determining thermal characteristics for each component; and designing the substrate comprising a plurality of layers with etched conductive paths, and a plurality of vias associated therewith for making component interconnections, wherein the component locations are functionally related to the thermal characteristics of each component such that components with similar thermal characteristics are located adjacent each other (and may also be thermally isolated from other components with different thermal characteristics).
E2. The method of example E1, further comprising locating a temperature measurement in an identified location on the surface of the SiP device to determine its case temperature.
E3. The method of example E1 or E2, further comprising locating/marking/using multiple locations for measuring case temperature.

While various embodiments of the present disclosure are described herein, it should be understood that they have been presented by way of example only, and not by way of any limitation. Thus, the breadth and scope of the present disclosure should not be limited by any of the herein above-described exemplary embodiments. Moreover, any combination of the herein above-described elements in all possible variations thereof is encompassed by the disclosure unless otherwise indicated herein or otherwise clearly contradicted by context. Accordingly, other embodiments, variations, and improvements not described herein are not excluded from the scope of the present disclosure. Such variations include but are not limited to new substrate material, different kinds of devices attached to the substrate not discussed, or new packaging concepts.

Additionally, while the processes described above and illustrated in the drawings are shown as a sequence of steps, this was done solely for the sake of illustration. Accordingly, it is contemplated that some steps may be added, some steps may be omitted, the order of the steps may be re-arranged, and some steps may be performed in parallel.

1-39. (canceled)

40. A System in a Package, SiP, apparatus, comprising:
a substrate having a plurality of layers with etched conductive paths and a first plurality of vias associated therewith for making operative interconnections between devices mounted on the substrate;
a first active device mounted in a first area of the substrate and having a first maximum operating temperature or tolerance;
a second active device mounted in a second area of the substrate and having a second maximum operating temperature or tolerance; and
a thermal barrier that thermally isolates the first device from the second device.

41. The apparatus of claim 40, wherein the thermal barrier is comprised of a plurality of components selected from surface-mount resistors and other passive devices.

42. The apparatus of claim 41, wherein the plurality of components are arranged in one or more arrays.

43. The apparatus of claim 42, wherein the one or more arrays comprise one or more of:
(i) two or more rows of components,
(ii) three or more rows of components,
(iii) a first row of components aligned in a first direction and a second row of components aligned in a second direction, or
(iv) a first row of components aligned in a first direction and a second row of components aligned in a second direction, wherein the first and second direction are orthogonal.

44. The apparatus of claim 40, wherein the first device generates more heat than the second device.

45. The apparatus of claim 40, wherein the thermal barrier is mounted on an upper surface of the substrate.

46. The apparatus of claim 40, further comprising:
a plurality of connection elements on a bottom surface of the substrate,
wherein the thermal barrier comprises one or more additional vias extending from a top surface of the substrate to the bottom surface of substrate, and
wherein at least one of the additional vias forms a thermal junction with at least one of the connection elements in an intersection at the bottom surface of the substrate.

47. The apparatus of claim 40, further comprising:
an encapsulant formed over at least the first and second device.

48. The apparatus of claim 47, wherein the thermal barrier comprises a gap in the encapsulant between the first and second device.

49. The apparatus of claim 40, further comprising:
a first heat sink,
wherein the first heat sink is located above or below the first active device, and is not above or below the second device.

50. The apparatus of claim 49, wherein the first heat sink is also located above or below the thermal barrier.

51. The apparatus of claim 49, further comprising:
a second heat sink,
wherein the second heat sink is located above or below the second active device, and is not above or below the first device.

52. The apparatus of claim 40, wherein the first device is a processing element or power management integrated circuit (PMIC) and the second device is a memory.

53. The apparatus of claim 40, wherein the thermal barrier comprises a gap in one or more conductive traces in the substrate between the first and second active devices.

54. The apparatus of claim 40, wherein the thermal barrier comprises a gap in a ball grid array on a bottom surface of the substrate.

55. The apparatus of claim 40, wherein the substrate comprises a plurality of layers with etched conductive paths and a plurality of vias associated therewith for making operative interconnections between the first and second devices and one or more components of the thermal barrier.

56. The apparatus of claim 40, further comprising:
at least one marking on an exterior surface of the apparatus identifying one or more locations for measuring operational temperatures of the apparatus.

57. The apparatus of claim 56, wherein the marking is on an exterior surface of the apparatus at the location of the second device.

58. The apparatus of claim 57, wherein the second active device is the most temperature sensitive component of the SiP.

59. The apparatus of claim 56, wherein the marking is a circular marking.
